(19) United States
(12) Patent Application Publication
(10) Pub. No.: US 2003/0076097 A1
(43) Pub. Date: Apr. 24, 2003

(54) Tuning of sensor resonant frequency in a magnetic field

(75) Inventors: Ruan Lourens, Chandler, AZ (US); Paul Forton, Chandler, AZ (US); Michel Sonnabend, Gilbert, AZ (US)

Correspondence Address: BAKER BOTTS, LLP, 910 LOUISIANA, HOUSTON, TX, 77002-4995, US

(73) Assignee: Microchip Technology Incorporated

(21) Appl. No.: 09/983,010

(22) Filed: Oct. 18, 2001

(51) Int. Cl. G01R 33/00

(52) U.S. Cl. 324/260

(57) ABSTRACT

Evaluation and optimization of a magnetic sensor embedded in a key-fob transponder used in a passive keyless entry system is achieved with a test circuit comprising a signal generator and coil from which a time varying amplitude magnetic field is generated. The magnetic sensor is placed in the magnetic field and the frequency-amplitude characteristics are determined by varying the frequency of the signal generator. Orientation of the magnetic sensor with the magnetic field is also determinative of the characteristics and operation of the sensor. A simulated load and signal strength indicator is temporarily coupled to the output of the magnetic sensor during evaluation of how the sensor will function when connected to the normal input circuits of the PKE transponder.

### RELATED APPLICATIONS

This application is related to co-pending patent applications Ser. No. ______ attorney docket number 068354.1169/MTI-1870], entitled “Apparatus and Method of Increasing the Sensitivity of Magnetic Sensors Used in Inductively Coupled Magnetic Field Transmission and Detection Systems,” filed Oct. 18, 2001, by Ruan Lourens, Steven Dawson and Pieter Schieke, and to Ser. No. ______ [attorney docket number 068354.1179/MTI-1892], entitled “Reducing Orientation Directivity and Improving Operating Distance of Magnetic Sensor Coils in a Magnetic Field,” filed Oct. 18, 2001, by Ruan Lourens, both applications are hereby incorporated by reference herein for all purposes.

### FIELD OF THE INVENTION

The present invention relates generally to inductively coupled magnetic field transmission and detection systems, such as passive keyless entry (PKE) systems, and more particularly to an apparatus and method for improving the sensitivity of magnetic sensors employed in such systems.

### BACKGROUND OF THE INVENTION TECHNOLOGY

The use of passive keyless entry (PKE) systems in automobile, home security, and other applications has increased significantly recently. These systems have increased the convenience of entering an automobile, for example, especially when the vehicle operator's hands are full, for example, with groceries. They also are more secure than prior key-based security systems.

These wireless PKE systems typically are comprised of a base station, which is normally placed in the vehicle in automobile applications, or in the home in home applications, and one or more PKE transponders, e.g., key-fobs, communicate with the base station. In simplest terms, the base station acts as an interrogator sending a signal within a magnetic field, which can be identified by a PKE transponder. The PKE transponder acts as a responder by transmitting an electromagnetic response signal, which can be identified by the base station (e.g., uniquely coded signals). The base station generates a time varying magnetic field at a certain frequency. When the PKE transponder is within a sufficiently strong enough magnetic field generated by the base station, the PKE transponder will respond if it recognizes its code, and if the base station and PKE transponder have matching codes the door will unlock. Thus, the PKE transponder is adapted to sense in a magnetic field, a time varying amplitude magnetically coupled signal at a certain frequency. The magnetically coupled signal carries coded information (amplitude modulation of the magnetic field), which if the coded information matches what the PKE transponder is expecting, will cause the PKE transponder to communicate back to the base station via a radio frequency signal (electromagnetic wave).

The base station typically comprises a magnetic field generating coil coupled to a signal generator and an electromagnetic signal receiving antenna coupled to a receiver. A single coil, e.g., multi-turn wire inductor may be used for both the magnetic field generation from the base station interrogator and as the electromagnetic signal receiving antenna for reception of the acknowledgment signal from the PKE transponder. Typically, the frequency used for generation of the time varying magnetic field is at low frequencies, e.g., about 125 kHz (Kilohertz). When one coil is used for both magnetic field generation and electromagnetic reception, the PKE transponder also transmits at low frequency response signal, typically at the same frequency as the interrogator magnetic field generator. More advanced wireless systems may use a very high frequency (VHF) or ultra high frequency (UHF) transmission response signal, e.g., 433.92 MHz. The advantage to using a higher frequency for the response signal is greater range with lower power than what is possible with only magnetic coupling between the base station interrogator and the PKE transponder. Also small antenna size is not as distance limiting at VHF and UHF frequencies.

The PKE transponder is typically housed in a small, easily carried key-fob and the like. A very small internal battery is used to power the electronic circuits of the PKE transponder when in use. The duty cycle of the PKE transponder must, by necessity, be very low otherwise the small internal battery would be quickly drained. Therefore to conserve battery life, the PKE transponder spends most of the time in a “sleep mode,” only being awakened when a sufficiently strong magnetic field interrogation signal is detected. The PKE transponder will awaken when in a strong enough magnetic field at the expected operating frequency, and will respond only after being thus awakened and receiving a correct security code from the base station interrogator, or if a manually initiated “unlock” signal is requested by the user (e.g., unlock push button on key-fob).

Thus, it is necessary that the number of false “wake-ups” of the PKE transponder circuits be keep to a minimum. This is accomplished by using low frequency time varying magnetic fields to limit the interrogation range of the base station to the PKE transponder. The VHF or UHF response transmission from the PKE transponder to the base station interrogator is effective at a much greater distance and at a lower transmission power level. Thus, walking through a shopping mall parking lot will not cause a PKE transponder to be constantly awakened. The PKE transponder will thereby be awakened only when within close proximity to the correct vehicle. The proximity distance necessary to wake up the PKE transponder is called the “read range.”

The read range is critical to acceptable operation of a PKE system and is normally the limiting factor in the distance at which the PKE transponder will awaken and decode the time varying magnetic field interrogation signal. There have been various approaches for improving the read range of the magnetic field by the PKE transponder. One such approach has been to increase the PKE transponder's electrical sensitivity to the output of a magnetic sensor (e.g., an inductor). This requires a very sensitive and high gain stage(s) that increases both PKE transponder cost and battery power consumption. Another approach is to improve the sensitivity of the magnetic sensor in the magnetic field. This approach typically requires a larger inductor and/or more costly coil materials and complex construction. Both approaches have merit, but from a cost and power consumption perspective the better solution is to improve the sensitivity of the magnetic sensor to the desired magnetic field.

In a typical PKE system, a base station (interrogator) initiates communications (the “read process”) by transmitting an amplitude modulated magnetic signal. If the correct PKE transponder receives this magnetic signal, then it communicates back to the base station via a RF signal, e.g., 433.92 MHz (the “response process”). It is therefore of fundamental importance that the PKE transponder receives the magnetic field signal correctly at the required distance away from the base station so that there may be a proper response sent thereafter. The effective RF response distance (typically 30 meters) is normally over an order of magnitude greater than the magnetic field range (typically about 1.5 meters). Therefore the critical parameter in an PKE system is the effective magnetic field communications range.

The most obvious way to increase PKE transponder read distance is to increase the amplitude of the generated magnetic field. However, there are legal limits to the amount of power in the transmitted magnetic field at a specified distance from the transmitting coil. Therefore the total transmitted magnetic field power must remain at no more than a legally mandated maximum fixed value. Therefore, the only way to increase PKE transponder read distance is to more efficiently use the available flux density of the magnetic field at a desired point in space.

The flux density of the magnetic field is also known as “field intensity” and is what the magnetic sensor senses. The field intensity decreases as the cube of the distance from the source, i.e., 1/d³. Existing PKE key-fob sensors have a very limited range because the magnetic sensor pick-up coils, by necessity, are small and thus have poor sensitivity when the key-fob is not in direct proximity to the base station magnetic field.

In actual operation in a PKE system, the pick-up coil is excited in a time varying amplitude magnetic field. When magnetic flux lines cut a coil of wire, an electric current is generated, i.e., see Maxwell's Equations for current flow in an electric conductor being cut by a magnetic field flux. Therefore the detected magnetic flux density will be proportional to the amount of current flowing in the pick-up coil. Attempts have been made to increase the read range of the PKE key-fob sensors by “tuning” the magnetic field pick-up coil to the frequency at which the base station interrogator magnetic signal generator is operating. Tuning is accomplished by electrically coupling an alternating current (AC) signal at the frequency of interest to the PKE key-fob pick-up coil and then tuning the coil for maximum signal amplitude. However, directly electrically exciting the pick-up coil does not take into account the magnetic environment surrounding and proximate to the pick-up coil sensor. The magnetic pick-up coil sensor has a magnetic directional sensitivity and extraneous magnetic field modifying influences that are not accounted for when only electrically exciting this pick-up coil. There may be magnetic interaction of the sensor in test with other sensors in the PKE key-fob and would not be apparent when using directly connected electrical excitation. Accurate testing and measurement equipment is also extremely expensive when trying to directly electrically tune the pick-up coil. In addition, the pick-up coil sensors are very sensitive to external circuit loading, any extraneous loading, as small as a few picofarads and/or as high as a few megohms, can influence the resonant frequency, quality factor (Q) and sensitivity of magnetic sensor coil.

Therefore, there is a need for improving the sensitivity and efficiency of electromagnetic field sensors in PKE systems by accurately tuning the sensors under substantially the same environment as is found in actual operation thereof.

### SUMMARY OF THE INVENTION

The present invention overcomes the above-identified problems as well as other shortcomings and deficiencies of existing technologies by providing an apparatus and method for optimizing the sensitivity of magnetic sensors in a magnetic field. The apparatus is cost effective, small in size, and well suited for incorporation into key-fobs used in passive keyless entry (PKE) systems.

In an exemplary embodiment of the present invention, the apparatus for optimizing the sensitivity of a magnetic sensor is provided. The magnetic sensor is electrically coupled to a signal amplitude level indicator circuit having input impedance characteristics which closely match the input impedance characteristics of the PKE circuit to which the magnetic sensor will ultimately be connected in normal operation. A signal generator provides an alternating current signal which is coupled to a test coil whose self-resonant frequency is well above the operating frequency of the signal generator. The signal provided by the signal generator produces a time varying electric field around the test coil, thereby creating a time varying intensity magnetic field at the frequency of the signal generator.

The sensor coil to be tested is disconnected from its associated electronic amplification circuit, and then connected to a signal amplitude measuring device which substantially replicates the input impedance of the normally connected electronic circuit. The magnetic sensor may be tested (evaluated) with its associated housing, other magnetic sensors, electronic circuits and battery of the PKE key-fob so as to closely simulate the characteristics of an operating PKE transponder. The magnetic sensor to be tested is placed within the generated magnetic field and the sensor output is measured as the signal generator frequency is swept until the maximum output voltage is measured. The frequency at which there is a maximum output voltage from the sensor is the “resonant frequency” of the sensor. In a similar manner, the 3 dB (and other amplitude values vs. frequency) points above and below the resonant frequency may also be determined. Once an amplitude vs. frequency plot is made of the sensor in the magnetic field, the resonant frequency, the bandwidth and quality factor (Q) of the sensor may be determined. Once the resonant frequency, bandwidth and Q are determined, and the desired characteristics of the sensor coil are not achieved, the sensor coil may be adjusted or tuned so as to meet the desired criteria. Adjustment of the sensor coil may be performed by component substitution and/or adjustment of variable tuning components of the PKE transducer. In addition, the PKE key-fob may have various sensors to cover different directions of magnetic field excitation. The present invention allows accurate positioning at various orientations in the magnetic field so that the performance of each of the various sensors may be determined, and if necessary, optimized.

In another exemplary embodiment of the present invention, a method of optimizing the sensitivity of a magnetic sensor is provided. The method includes the steps of driving a test coil with a signal generator so as to produce a time varying magnetic field around the test coil. Connecting a magnetic sensor to a measuring device having a similar impedance as the input of a circuit the magnetic sensor is electrically coupled. Placing a magnetic sensor to be tested within the test coil magnetic field. Sweeping the frequency of the signal generator so as to obtain an amplitude versus frequency response of the magnetic sensor under test. In addition, the components of the magnetic sensor may be adjusted so that the sensor is resonant at a desired frequency.

A technical advantage of the present invention is easier optimization of the operation of a sensor at a desired frequency. Another technical advantage is accurate measurement of the frequency response characteristics of a magnetic sensor in its actual operating environment. Another technical advantage is determination of necessary compensation for magnetic influences in the operating environment of the sensor. Another technical advantage is low cost of implementation of the testing system. Still another technical advantage is accurate repeatability of the determination of the characteristics of magnetic sensors under test. Another technical advantage is close approximation of the actual operating system in which the magnetic sensor will be used.

### BRIEF DESCRIPTION OF THE DRAWINGS

A more complete understanding of the present disclosure and advantages thereof may be acquired by referring to the following description taken in conjunction with the accompanying drawings wherein:

FIG. 1 is a schematic block diagram of a prior technology test circuit and system for optimizing a sensor coil;

FIG. 2 is a schematic block diagram of a magnetic field generator for testing and determining the operating characteristics of a magnetic sensor, according to the present invention; and

FIG. 3 is a voltage amplitude versus frequency graph illustrating the characteristics of a magnetic sensor coil under test.

The present invention may be susceptible to various modifications and alternative forms. Specific embodiments of the present invention are shown by way of example in the drawings and are described herein in detail. It should be understood, however, that the description set forth herein of specific embodiments is not intended to limit the present invention to the particular forms disclosed. Rather, all modifications, alternatives, and equivalents falling within the spirit and scope of the invention as defined by the appended claims are intended to be covered.

### DETAILED DESCRIPTION OF THE SPECIFIC EMBODIMENTS

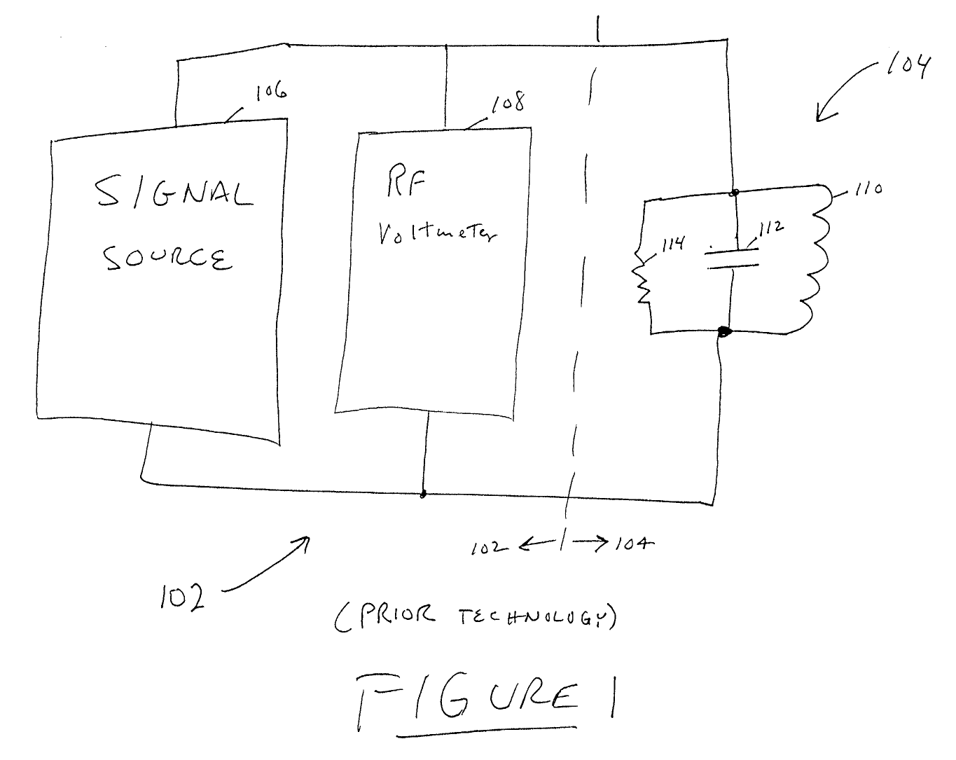

Referring now to the drawings, the details of an exemplary specific embodiment of the invention is schematically illustrated. FIG. 1 illustrates a schematic block diagram of a prior technology test circuit and system for optimizing a sensor coil. A test circuit, generally represented by the numeral 102 comprises a signal source 106 and a RF voltmeter 108 connected in parallel with the output of the signal source 106. The magnetic sensor, generally represented by the numeral 104 comprises an inductor 110, a capacitor 112 and a resistor 114. The output of the signal source 106 is connected in parallel with the inductor 110, capacitor 112 and resistor 114. The signal source 106 is adjusted in frequency for a maximum voltage amplitude as determined by the RF voltmeter 108. The frequency at which a maximum voltage amplitude is found is the parallel resonant frequency of the magnetic sensor 104. However, this test circuit 102 may not be accurate because a directly connected electromagnetic signal is being used to determine the resonant frequency characteristics of the sensor 104. The test circuit 102 cannot be used to determine any magnetic influences that may affect the resonant frequency and magnetic characteristics of the sensor 104.

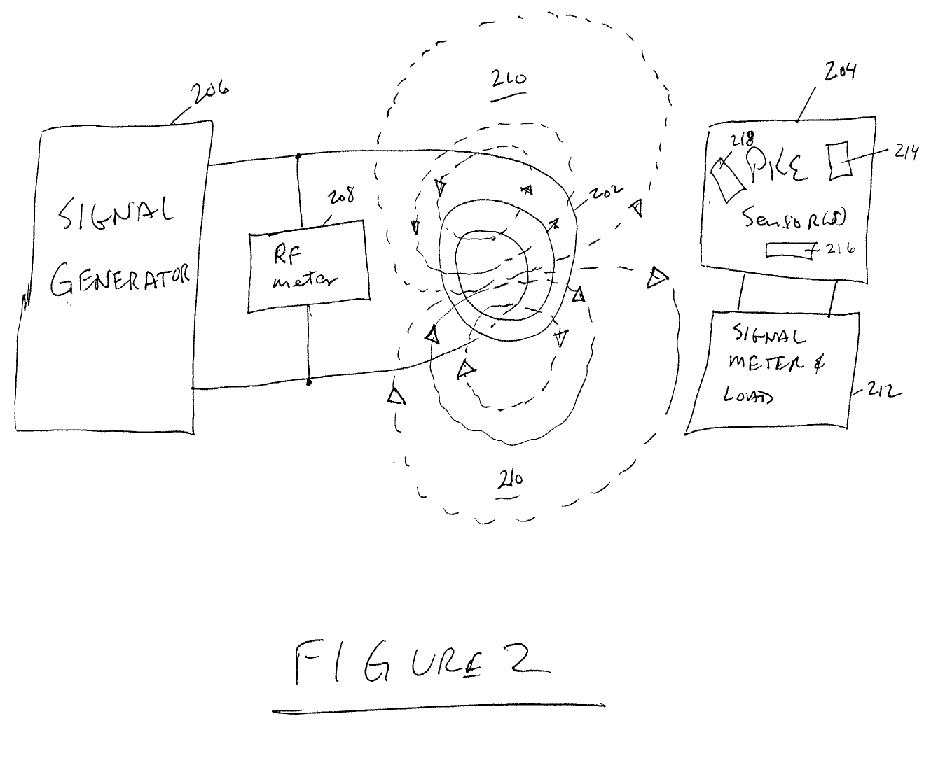

Referring now to FIG. 2, depicted is a schematic block diagram of a magnetic field generator for testing and determining the operating characteristics of a magnetic sensor, according to the present invention. A signal generator 206 is electrically coupled to a coil 210, and a RF meter 208 may be coupled across the output of the signal generator 206. The self-resonant frequency of the test coil 210 is well above the test frequencies of the signal generator 206. Therefore, there is predominately a magnetic field 210 surrounding the test coil 202. When the PKE key-fob 204 is brought into the magnetic field 210, the magnetic sensors 214, 216 and 218 detect the changing magnetic flux and currents thereby flow in each of the sensor coils (not illustrated). A signal meter and load 212 may be temporarily connected to each of the sensors 214, 216 and 218 during the determination of the magnetic detection characteristics thereof. The signal generator 206 is swept through a certain range of frequencies while measuring the output signal amplitude from each of the sensors 214, 216 and 218 with the signal meter and load 212. The signal meter and load 212 is similar in characteristic impedance to the actual PKE circuits to which the sensor under test is normally connected. Using a test load having the same characteristic impedance as the actual circuits being driven by the sensors yield more accurate frequency responses for the sensors 214, 216 and 218 being tested. Using an actual magnetic field 210 to test the sensors 214, 216 and 218 takes into account all factors which may influence the sensor's magnetic detection characteristics.

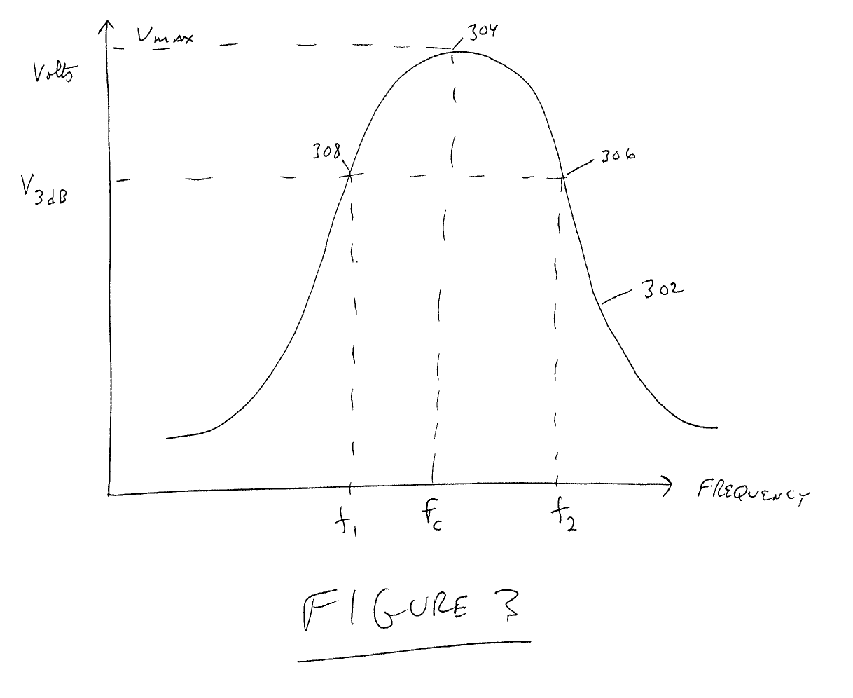

Referring to FIG. 3, depicted is a voltage amplitude versus frequency graph illustrating the characteristics of a magnetic sensor coil under test. When the frequency of the signal generator 206 is swept from below f₁ to above f₂, an amplitude-frequency response curve is obtained for the sensor under test. When the generator 206 frequency is at the sensor's resonant frequency, f_{c}, the amplitude at point 304 on the graph is at a maximum. When the generator 206 frequency is at either of the 3 dB power points 306, 308, the amplitude is half of the amplitude at 304 (6 dB voltage). The difference in frequency between f₂ and f₁ is the 3 dB bandwidth of the sensor. Knowing bandwidth and the resonant frequency, f_{c}, the quality factor (Q) of the sensor circuit may be calculated.

The present invention has been described in terms of exemplary embodiments. In accordance with the present invention, the parameters for a system may be varied, typically with a design engineer specifying and selecting them for the desired application. Further, it is contemplated that other embodiments, which may be devised readily by persons of ordinary skill in the art based on the teachings set forth herein, may be within the scope of the invention, which is defined by the appended claims. The present invention may be modified and practiced in different but equivalent manners that will be apparent to those skilled in the art and having the benefit of the teachings set forth herein.

What is claimed is:

1. An apparatus for evaluating frequency response of a sensor in a magnetic field, comprising:
a signal generator;
a test coil electrically coupled to the signal generator, wherein a signal from the signal generator causes a magnetic field to be created around the test coil;
a magnetic sensor located in the magnetic field;
a test load coupled to the magnetic sensor, wherein the test load has similar impedance characteristics to a load normally coupled to the magnetic sensor;and
a signal meter coupled to the magnetic sensor, the signal meter indicating the relative amplitude of the magnetic field at the magnetic sensor.

2. The apparatus according to claim 1, wherein the test coil has a self-resonance much higher than any signal frequency from the signal generator.

3. The apparatus according to claim 1, wherein the magnetic sensor is enclosed in a passive keyless entry (PKE) key-fob.

4. The apparatus according to claim 3, wherein the PKE key-fob comprises a plurality of magnetic sensors.

5. The apparatus according to claim 4, wherein each of the plurality of magnetic sensors is located in the magnetic field, and has the test load and signal meter coupled thereto.

6. The apparatus according to claim 1, wherein a frequency-amplitude plot is computed for the magnetic sensor by varying the signal generator frequency and measuring the relative amplitudes for each of the signal generator frequencies applied to the magnetic sensor.

7. The apparatus according to claim 5, wherein a frequency-amplitude plot is computed for each of plurality of magnetic sensors by varying the signal generator frequency and measuring the relative amplitudes for each of the signal generator frequencies applied to each of the plurality of magnetic sensors.

8. The apparatus according to claim 1, wherein the magnetic sensor is tuned to a desired resonant frequency.

9. The apparatus according to claim 4, wherein each of the plurality of magnetic sensors is tuned to a desired resonant frequency.

10. A method for evaluating frequency response of a sensor in a magnetic field, said method comprising:
generating an electromagnetic signal with a signal generator;
creating a magnetic field around a test coil with the signal from the signal generator;
coupling a signal meter to a magnetic sensor;
locating the magnetic sensor in the magnetic field; and
measuring the relative amplitude of the magnetic field at the magnetic sensor.

11. The method according to claim 10, after the step of coupling a signal meter, further comprising the step of coupling a test load to the magnetic sensor, wherein the test load has similar impedance characteristics to a load normally coupled to the magnetic sensor.

12. The method according to claim 10, wherein the test coil has a self-resonance much higher than any signal frequency from the signal generator.

13. The method according to claim 10, wherein the magnetic sensor is enclosed in a passive keyless entry (PKE) key-fob.

14. The method according to claim 13, wherein the PKE key-fob comprises a plurality of magnetic sensors.

15. The method according to claim 14, wherein each of the plurality of magnetic sensors is located in the magnetic field, and has the test load and signal meter coupled thereto.

16. The method according to claim 10, further comprising the step of determining a frequency-amplitude graph for the magnetic sensor by varying the signal generator frequency and measuring the relative amplitudes for each of the signal generator frequencies applied to the magnetic sensor.

17. The method to claim 15, further comprising the step of determining a frequency-amplitude graph for each of plurality of magnetic sensors by varying the signal generator frequency and measuring the relative amplitudes for each of the signal generator frequencies applied to each of the plurality of magnetic sensors.

18. A system for optimizing detection sensitivity of a magnetic sensor at a desired frequency, said system comprising:
a signal generator;
a test coil electrically coupled to the signal generator, wherein a signal at a desired frequency from the signal generator causes a magnetic field to be created around the test coil;
a magnetic sensor located in the magnetic field;
a test load coupled to the magnetic sensor, wherein the test load has similar impedance characteristics to a load normally coupled to the magnetic sensor; and
a signal meter coupled to the magnetic sensor, the signal meter indicating the relative amplitude of the desired frequency of the magnetic field at the magnetic sensor.

19. The system according to claim 1b, wherein the magnetic sensor is tuned to the desired signal frequency from the signal generator.

20. The system according to claim 18, wherein a plurality of magnetic sensors are located in the magnetic field and each of the plurality of magnetic sensors are tuned to the desired signal frequency.
